(19) United States
(12) Patent Application Publication
(10) Pub. No.: US 2023/0023287 A1
(43) Pub. Date: Jan. 26, 2023

(54) COOLING SYSTEM, COOLING METHOD AND COMPUTER READABLE MEDIUM

(71) Applicant: NEC Corporation, Minato-ku, Tokyo (JP)

(72) Inventors: Nilmal Singh RAJPUT, Tokyo (JP); Koichi TODOROKI, Tokyo (JP); Takafumi NATSUMEDA, Tokyo (JP); Mahiro HACHIYA, Tokyo (JP); Minoru YOSHIKAWA, Tokyo (JP)

(73) Assignee: NEC Corporation, Minato-ku, Tokyo (JP)

(21) Appl. No.: 17/791,077

(22) PCT Filed: Jan. 16, 2020
(86) PCT No.: PCT/JP2020/001314

§ 371 Date: Jul. 6, 2022

(51) Int. Cl. H05K 7/20

(52) U.S. Cl. CPC H05K 7/20836; H05K 7/20145; H05K 7/20745

(57) ABSTRACT

A cooling system (100) has a housing (101), a heat exchanger (110) and an air distribution controller (120). The housing (101) including an inlet (102) for receiving air exhausted from the server module and an outlet (103) for providing air to the server module. The heat exchanger (110) is mounted between the inlet (102) and the outlet (103), the heat exchanger (110) is configured that a refrigerant (111) contained in the heat exchanger (110) exchanges heat with air passing through the heat exchanger (110). The heat exchanger (110) accepts variation of the refrigerant liquid level. The air distribution controller (120) is mounted in an inlet side of the heat exchanger (110). The air distribution controller (120) has a movable plate which allows an airflow profile from the inlet to the heat exchanger (110) redirected. The air distribution controller (120) controls the airflow profile depending on the liquid level.

### TECHNICAL FIELD

The present invention relates to a cooling system, a cooling method and program.

### BACKGROUND ART

Along with the progress made in cloud services or the like, to handle explosive data traffic, the accommodation of data centers has been increased. Accordingly, technologies for cooling server systems at the data centers with high-efficiency are demanded.

Patent Literature 1 (WO2017/199444) discloses a system having a centrifugal blower and a heat exchanger. The centrifugal blower to be accommodated in a housing having an air inlet includes a spiral casing having a bell mouth and a centrifugal fan housed in the casing. The heat exchanger is disposed in an air flow path inside the housing.

### CITATION LIST

### Patent Literature

PTL 1: WO2017/199444

### SUMMARY OF INVENTION

### Technical Problem

The system disclosed in the prior art utilizes fans to move air across a heat exchanger. However, since a cooling capacity of the heat exchanger is not always constant at a rated cooling capacity, an unutilized portion in the heat exchanger still remains in the case of two-phase heat transfer applications. Therefore, there is room for achieving an improvement in the efficiency of heat transferring.

An example object of the present disclosure is to solve one of the above-described problems.

### Solution to Problem

An aspect of the present invention is a cooling system for cooling a server module. The system has a housing, a heat exchanger and an air distribution controller. The housing including an inlet configured to receive air exhausted from the server module and an outlet configured to provide air to the server module. The heat exchanger is mounted between the inlet and the outlet, the heat exchanger is configured so that a refrigerant contained in the heat exchanger exchanges heat with air passing through the heat exchanger, wherein the heat exchanger accepts variation of the refrigerant liquid level. The air distribution controller is mounted in an inlet side of the heat exchanger. The air distribution controller has at least one movable plate which allows an airflow profile from the inlet to the heat exchanger to be redirected. The air distribution controller controls the airflow profile depending on the liquid level.

An aspect of the present invention is a cooling method for a cooling system. The cooling system includes a heat exchanger containing a refrigerant and an air distribution controller. The cooling method includes an acquiring a cooling capacity step, a liquid level estimation step and an air distribution control step. The acquiring the cooling capacity step is a step in which the cooling capacity of the heat exchanger is calculated based on a temperature at a predetermined point of the cooling system. The liquid level estimation step is a step in which the liquid level of the heat exchanger is estimated based upon the cooling capacity. The air distribution control step is a step in which the air distribution controller redirects the airflow profile depending upon the liquid level.

An aspect of the present invention is a non-transitory computer readable medium storing a program for causing a computer to execute a cooling method for a cooling system. The cooling system includes a heat exchanger containing a refrigerant and an air distribution controller. The cooling method includes an acquiring a cooling capacity step, a liquid level estimation step and an air distribution control step. The acquiring the cooling capacity step is a step in which the cooling capacity of the heat exchanger is calculated based on a temperature at a predetermined point of the cooling system. The liquid level estimation step is a step in which the liquid level of the heat exchanger is estimated based upon the cooling capacity. The air distribution control step is a step in which the air distribution controller redirects the airflow profile depending upon the liquid level.

### Advantageous Effects of Invention

According to the present invention, it is possible to provide a cooling system and the like which can implement heat transfer with high efficiency.

### BRIEF DESCRIPTION OF DRAWINGS

FIG. 1 is a first schematic view of a cooling system according to a first example embodiment.

FIG. 2 is a second schematic view of the cooling system according to the first example embodiment.

FIG. 3 is a schematic view of a data center including a cooling system according to a second example embodiment.

FIG. 4 is a first schematic view of a cooling system according to the second example embodiment.

FIG. 5 is a functional block diagram of the cooling system according to the second example embodiment.

FIG. 6 is a diagrammatic illustration of a louver in an air distribution controller of the cooling system.

FIG. 7 is a table illustrates a relation between an open ratio and CR.

FIG. 8 is a second schematic view of a cooling system according to a second example embodiment.

FIG. 9 is a flowchart of the cooling system according to the second example embodiment.

FIG. 10 is a first schematic view of a cooling system according to a third example embodiment.

FIG. 11 is a second schematic view of a cooling system according to the third example embodiment.

### EXAMPLE EMBODIMENT

Example embodiments of the present invention will be described below with reference to the drawings. In the drawings, the same elements are denoted by the same reference numerals, and thus repeated descriptions are omitted as needed.

### First Example Embodiment

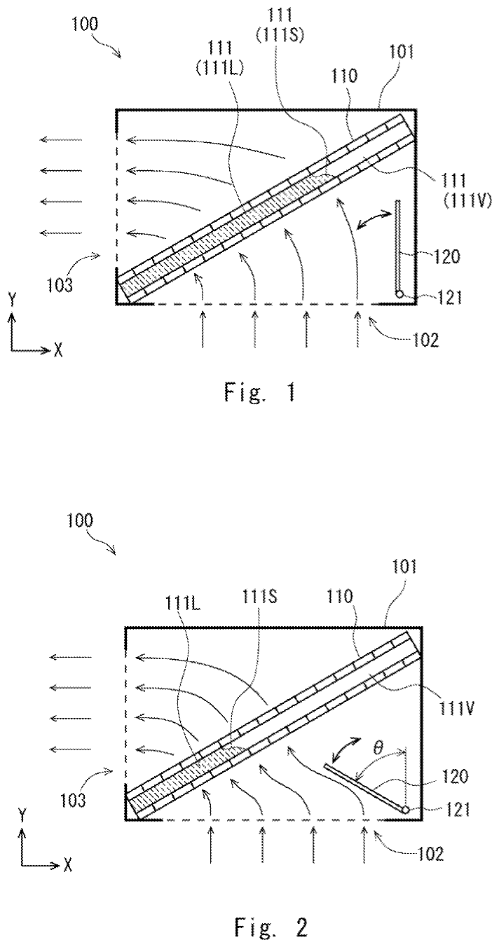

Hereinafter, with reference to the drawings, example embodiments of the present disclosure will be explained. FIG. 1 is a first schematic view of a cooling system according to a first example embodiment. Note that an XY coordinate system is attached to FIG. 1 as an expedient for explaining the positional relationship of the constituent elements. In FIG. 2 and subsequent figures, when an XY coordinate system is attached thereto, the X-axis and Y-axis directions in FIG. 1 and the X-axis and Y-axis directions of these coordinate systems respectively match.

The cooling system 100 shown in FIG. 1 is utilized for cooling a server module installed in a data center and the like. The outline of the cooling system 100 is substantially an approximately rectangular parallelepiped. FIG. 1 illustrates the section of the cooling system 100 cut in a XY plane. Therefore, such construction shown in FIG. 1 extends in a direction orthogonal to the XY plane. The cooling system 100 includes a hosing 101, a heat exchanger 110 and an air distribution controller 120.

The housing 101 is a console which houses components of the cooling system 100. The housing 101 may have a structure for mounting it on equipment in which a data center or the like is installed. The housing 101 includes an inlet 102 and outlet 103. The inlet 102 has an opening for receiving air exhausted from the server module into the housing 101. The outlet 103 has an opening for providing air from inside the housing 101 to the server module. As shown in FIG. 1, the housing 101 has the inlet 102 at its bottom side and the outlet 103 at its left side. Therefore, the cooling system 100 shown in FIG. 1 receives air exhausted from the server module at its bottom side and exhausts air from its left side. The inlet 102 and the outlet 103 may include air filter.

The heat exchanger 110 is mounted between the inlet 102 and the outlet 103 in the housing 101. As shown in FIG. 1, the heat exchanger 110 extends from the lower left to the upper right along a diagonal line of the rectangular outline of the housing 101. The heat exchanger 110 contains a refrigerant 111. The refrigerant 111 can exchange heat with air passing through the heat exchanger.

The refrigerant 111 in the heat exchanger 110 exists as a liquid 111L or a vapor 111V. Further the liquid level of the refrigerant varies when the supply quantity from a means which supplies the liquid changes the quantity level. Note that, in this case, the liquid level refers to a position level of the liquid surface 111S in the refrigerant 111. That is, the heat exchanger 110 accepts variation of the refrigerant liquid level.

The structure of the heat exchanger 110 may be that of a typical heat exchanger such that the heat exchanger 110 has multiple tubes containing the liquid refrigerant and fins. Further, the heat exchanger 110 has multiple through holes or paths so that the air from the inlet 102 contacts the fins surface and passes to the outlet 103. The heat exchanger 110 is configured to extract thermal energy from air and transfer the thermal energy to the liquid refrigerant. Transferring the thermal energy from air to the liquid refrigerant results in the liquid being evaporate into a vapor. The heat exchanger 110 may be connected to a circulation system which allows the vapor to be captured from the heat exchanger 110 and liquid to be supplied thereto. Accordingly, the cooling system 100 may be configured for a vapor-compression refrigeration system or phase change cooling system. In other words, the cooling system 100 may be a part of such system.

The air distribution controller 120 is mounted in the inlet side of the heat exchanger 110. As shown in FIG. 1, the air distribution controller 120 is formed in a flat rectangle plate and has an axis 121 at a lower edge so that it can rotate about the axis 121. The air distribution controller is rotatable around the axis 121 and also is able to be fixed in a desired direction. The air distribution controller 120 allows an airflow profile from the inlet 102 to the heat exchanger 110 to be redirected. The direction of the air distribution controller 120 shown in FIG. 1 is in parallel to Y-axis. In this direction, the air distribution controller 120 doesn't interrupt airflow in the cooling system 100. Note that the air distribution controller 120 may be formed with a not-flat shape such as a curved shape, or a waved shape. The position of the axis 121 may be in a middle portion of the air distribution controller 120.

In FIG. 1, the air corning to the inlet 102 flows along in the Y-positive direction. The direction of the airflow coming into the cooling system via the inlet 102 then gradually changes to the upper left and passes through the heat exchanger 110. After passing through the heat exchanger 110, the direction of the airflow then gradually changes to the left and is exhausted from the outlet 103. In this case, air received at the right part of the inlet 102 (in X-direction) passes at the upper right part of the heat exchanger 110 and is exhausted at the upper part of the outlet 103 (in Y-direction). Also, an air received at the center part of the inlet 102 passes at the middle part of the heat exchanger 110 and is exhausted at the center part of the outlet 103. Similarly, air received at the left part of the inlet 102 passes at the lower left part of the heat exchanger 110 and is exhausted at the lower part of the outlet 103.

The air distribution controller 120 can redirect the airflow when it is rotated and fixed in another position. The air distribution controller 120 may be rotated by a mean to drive the air distribution controller 120 such as a motor or an actuator. The air distribution controller 120 may also be rotated by a user. The position of the air distribution controller 120 may be fixed depending on the liquid level of the refrigerant 111.

Next, another state in which the air distribution controller 120 redirects the airflow will be described in FIG. 2. FIG. 2 is a second schematic view of the cooling system according to the first example embodiment. One difference between FIG. 1 and FIG. 2 is liquid level of the refrigerant 111. In other words, the quantity of the refrigerant in the heat exchanger 110 shown in FIG. 2 is smaller than that of FIG. 1.

Another difference between FIG. 1 and FIG. 2 is the air distribution controller position. As shown in FIG. 2, the air distribution controller 120 is rotated counterclockwise about the axis 121 and fixed in a position where the angle between the plate and Y-axis is θ. In the state shown in FIG. 2, the air distribution controller 120 redirects an airflow intended to flow from the inlet 102 to the upper right portion of the heat exchanger 110 to the upper left.

The air distribution controller 120 redirects the air from the right part to the left part. As a result, for example, in this case, air received at the right part of the inlet 102 passes at the middle part of the heat exchanger 110 and is exhausted at the upper part of the outlet 103.

Although the first example embodiment has been described above, the configuration according to the first example embodiment is not limited to the above-described configuration. The air distribution controller 120 may include a plurality of plates for redirecting the airflow profile. The outline of the housing 101 is not limited to the shape above mentioned. An arbitrary shape may be adopted as the outline of the housing 101.

As mentioned above, the cooling system 100 can redirect the airflow passing through the heat exchanger 110 depending upon the liquid level. More concretely, the cooling system 100 can redirect the airflow profile passing through the heat exchanger 110 so that the airflow passes through the portion in where the heat exchanger 110 contains the liquid refrigerant. Hence, the cooling system 100 improves an efficiency of the heat transfer. As described above, according to the first example embodiment, it is possible to provide a cooling system and the like which can implement heat transfer with high efficiency.

### Second Example Embodiment

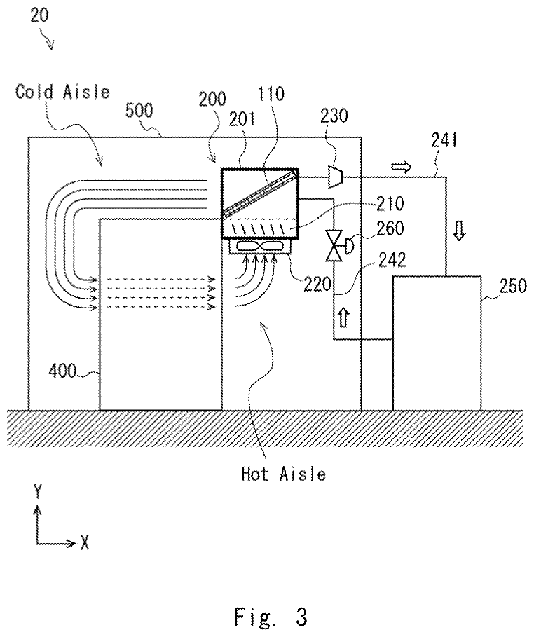

Hereinafter, second example embodiment will be described. FIG. 3 is a schematic view of a data center including a cooling system according to the second example embodiment. A data center 20, being illustrated in FIG. 3, has a main building 500 and an outdoor unit 250. The main building 500 mainly includes a cooling system 200, fan unit 220, compressor 230, valve unit 260 and a server module 400.

The main building 500 is configured to circulate air from server module 400 to the cooling system 200 and from the cooling system 200 to the server module 400. In the circulation system, the airflow from the server module 400 to the cooling system 200 is called “hot aisle”, while the airflow from the cooling system 200 to the server module 400 is called “cold aisle”. The cooling system 200 receives air exhausted from server module 400 via the hot aisle. Further, the cooling system 200 exhausts air, by which is absorbed heat, to the cold aisle and the air is provided to the server module 400. Then the server module 400 exhausts the air heated by the server module 400 to the hot aisle again. Note that such system shown in FIG. 3 also has a certain structure such like wall to separate the cold aisle and the hot aisle, although FIG. 3 is described schematically. The main building 500 may have a plurality of the server modules 400 and the corresponding cooling system 200.

The fan unit 220 is attached to the inlet of the cooling system 200. The fan unit 220 includes a fan motor to pump the air in the hot aisle to the cooling system 200. The server module 400 is composed of, for example, a server rack which can house at least one server computer. The server module 400 is configured to establish a pathway to receive the air from the cold aisle and to exhaust the air heated by the server computer to the hot aisle.

The cooling system 200 is configured to receive the air from the server module via the cold aisle and the fan unit 220, absorb the heat from the air by refrigerant contained in a heat exchanger 110 and exhaust the air which the heat has been absorbed to the cold aisle. The cooling system 200 includes an air distribution controller 210. The air distribution controller 210 in the present embodiment has a plural of plates to redirect the airflow profile. Note that the detail of the cooling system 200 will be described later.

The cooling system 200 and the outdoor unit 250 are connected each other by a first pipe 241 and a second pipe 242 so as to circulate the refrigerant among them. The first pipe 241 transfers a refrigerant which has absorbed the heat from the air in the heat exchanger 110. In the middle of the first pipe 241, the first pipe 241 has a compressor 230. The compressor 230 compresses the vapor evaporated in the heat exchanger 110 by absorbing the heat from the air which passes the heat exchanger 110. The outdoor unit 250 is configured to receive the compressed refrigerant, reject the heat from the refrigerant, condense refrigerant so as to the refrigerant becomes a liquid and pump the liquid refrigerant which the heat has been rejected to the cooling system 200 via the second pipe 242. In the middle of the second pipe 242, the second pipe 242 has a valve unit 260. The valve unit 260 is configured to control a supply quantity of liquid refrigerant to the heat exchanger 110 in the cooling system 200.

The cooling system 200 and other components connected to the cooling system 200 may be controlled by a control unit having arithmetic and logic unit such as CPU (Central Processing Unit) or MCU (Micro Controller Unit). Accordingly, operation of the cooling system 200, the fan unit 220, the compressor 230, the outdoor unit 250 and the valve unit 260 may be correlated or integrated.

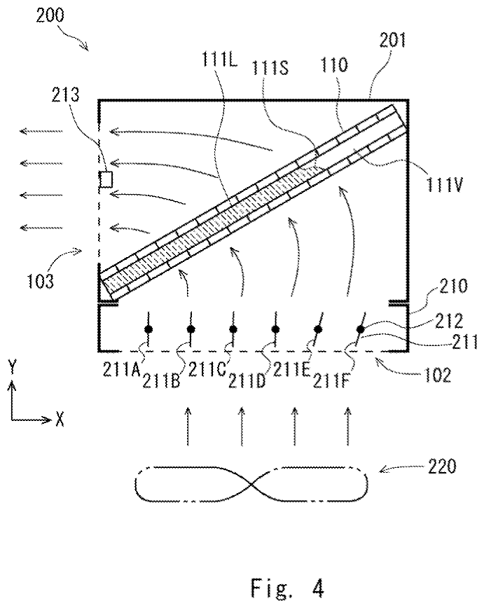

FIG. 4 is a first schematic view of a cooling system according to the second example embodiment. The cooling system 200 has a heat exchanger 110, a housing 201, a louver unit 210 and a temperature sensor 213. The main difference between the cooling system 200 and the cooling system 100 described in the first example embodiment is that the cooling system 200 has a louver unit 210 instead of the air distribution controller 120 and the cooling system 200 further has a temperature sensor 213.

The louver unit 210 is one aspect of the air distribution controller. The louver unit 210 is attached to the housing 201. The louver unit 210 has the inlet 102 to receive the air from the fan unit 220. Since the louver unit 201 is connected to the housing 201 so that the air flows successively, the housing 201 and the console of the louver unit 210 may be referred as housing. Therefore, it may be described that the housing 201 has the inlet 102.

The louver unit 210 has 6 louvers 211 (louver 211A to 211F). The louvers 211 are aligned along X-direction. Each louver 211 is formed in a flat rectangle plate and has an axis 212 at the middle of the plate in Y-direction so that it can rotate about the axis 212. The louvers 211 are driven by motors (not shown).

The direction of the louvers 211A to 211D shown in FIG. 4 is in parallel to Y-axis. The airflow profile at the area or the louver unit 210 is in parallel to Y-axis. Thus, at this direction, the louvers 211 don't interrupt airflow in the cooling system 200. The direction of the louvers 211E and 211F shown in FIG. 4 extends from lower-left to upper-right. Thus, at this area in the louver unit 210, the airflow profile directs toward slightly upper right. In this case shown in FIG. 4, air received at the right part of the inlet 102 passes at the upper right part of the heat exchanger 110 and is exhausted at the upper part of the outlet 103. Also, air received at the left part of the inlet 102 passes at the lower left part of the heat exchanger 110 and is exhausted at the lower part of the outlet 103.

The temperature sensor 213 detects a temperature of a point where the temperature sensor 213 is attached. The temperature sensor 213 is attached to a predetermined position such as the center part of the outlet 103 of the cooling system to monitor the air temperature. The temperature sensor 213 is connected to a controller (not shown) and provides a temperature data to the controller.

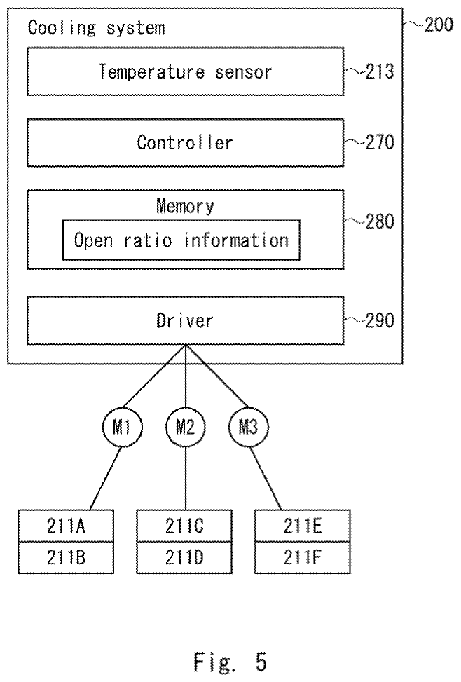

FIG. 5 is a functional block diagram of the cooling system according to the second example embodiment. The cooling system 200 includes the temperature sensor 213, a controller 270, a memory 280 and a driver 290. As mentioned above, the temperature sensor 213 detects the temperature where it is attached and provides the temperature data to the controller 270.

The controller 270 is composed of a certain combination of electronic devices and circuit which includes arithmetic and logic unit such as CPU, or MCU. The controller 270 can perform predetermined process by such components and the program installed in the controller 270. In other words, the controller 270 can perform predetermined process by the hardware and the software. The controller 270 is connected each component and configured to receive data from them and provide command signals to them. More specifically, the controller 270 receives the temperature data from the temperature sensor 213 and calculates current cooling capacity of the cooling system by utilizing the temperature data.

The current cooling capacity may be calculated by a following equation (1) and (2):

Q=mr×ΔH (1);

ΔH=Hout−Hin (2);

where Q is amount of energy transfer (kW), mr is refrigerant mass flow rate (kg/s) and ΔH is difference in enthalpy (KJ/kg) of refrigerant which can be calculated by subtracting enthalpy at heat exchanger outlet Hout from enthalpy at heat exchanger inlet Hin. The enthalpy at heat exchanger inlet and outlet can be calculated by measuring two physical variables such as temperature and pressure at required location by appropriate sensors.

Note that the current cooling capacity may also be calculated by a following equation (3):

Q=ma×Cp×ΔTma=p×qΔT=Tout—Tin (3);

where Q is amount of energy transfer (kW), ma is the rate of airflow mass flowing through heat exchanger (kg/s) which can be calculated by multiply air density p (kg/m3) and airflow rate q (m3/s) which can be measured by standard airflow measurement device. Cp is specific heat at constant pressure (KJ/kg·k) and ΔT is difference in temperature (K) of air which can be calculated by subtracting temperature at heat exchanger outlet Tout from temperature at heat exchanger inlet Tin. The temperature at heat exchanger inlet and outlet can be calculated by measuring temperature via standard thermocouple.

Also, the controller 270 acquires a rated cooling capacity of the cooling system 200. The rated cooling capacity indicates the capacity of the heat exchanger 110 of the cooling system 200. The rated cooling capacity refers to the amount of heat transport (W) per temperature difference 1 (K) of the heat exchanger 110. Since the rated cooling capacity is a value determined by the characteristics of the cooling system 200, the rated cooling capacity may be memorized in the memory 280.

Further, the controller 270 calculates a ratio of the current cooling capacity to the rated cooling capacity. Note that for the sake of convenience, the ratio of the current cooling capacity to the rated cooling capacity is referred to “CR” or “CR value”. Furthermore, the controller 270 fetches open ratio information from the memory 280 and determines each angle of louver 211 by referring the open ratio information. The open ratio information is information which indicates the relation between the open ratio of the louvers 211 and CR. Note that the detail of the open ratio information will be described later. The controller 270 supplies an indication signal to the driver 290 to set the louver angle.

The controller 270 may have other function for controlling other correlated components mentioned above such as the outdoor unit 250, or the valve unit 260 and the like. The controller 270 may connected to other system which controls the above mentioned components.

The memory 280 includes a non-volatile memory such as flash memory to memorize a certain data. The memory 280 memorizes at least open ratio information. The memory 280 supplies the open ratio information and the like in response to the indication from the controller 270.

The driver 290 includes motor driver circuit and controls three motors M1, M2 and M3. The driver 290 receives an indication from the controller 270, drives motors in accordance with the indication from the controller 270. In this example embodiment, the driver 290 controls the motors M1, M2 and M3 separately. That is, the driver 290 may drive these motors in different angle, or different timing.

The motor M1 is configured to rotate the louver 211A and 211B. Accordingly, the louver 211A and 211B is rotated simultaneously. Likewise, the louver 211C and 211D is rotated simultaneously while the motor M2 is configured to rotate the louver 211C and 211D. The louver 211E and 211F is rotated simultaneously while the motor M3 is configured to rotate the louver 211E and 211F.

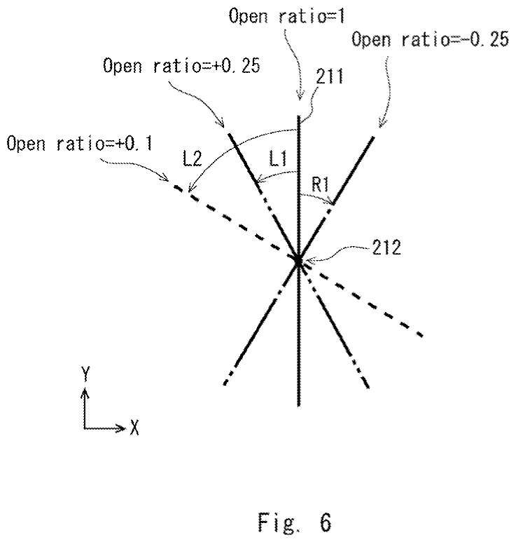

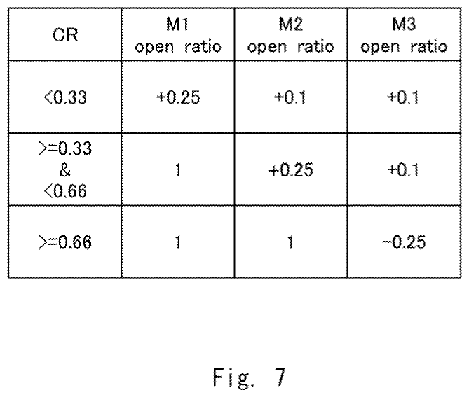

Next, how the louvers 211 are controlled by motors will be described by referring FIG. 6 and FIG. 7. FIG. 6 is a diagrammatic illustration of a louver in the air distribution controller of the cooling system. In FIG. 6, one louver 211 is shown by a full line in parallel to Y-axis. At this angle, the louver 211 doesn't interrupt airflow. Here, it is defined that the open ratio at this angle of the louver 211 is “1” where the 1 for the open ratio is maximum value. When the louver 211 rotates from the position as the open ratio 1, the open ratio value becomes smaller.

As shown in FIG. 6, three virtual lines are shown as example case. A line described by one-dot chain line indicates the louver 211 rotates in clock wise by angle R1. At this angle, it is defined that the open ratio is −0.25. In this case, the attached sign “−” indicates that the direction of its rotation is in clock wise. Further, the absolute value “0.25” indicates its angle between the lines at open ratio is 1 and 0.25.

A line described by two-dot chain line indicates the louver 211 rotates in counter clock wise by angle L1. At this angle, it is defined that the open ratio is +0.25. In this case, the attached sign “+” is referred that the direction of its rotation is in counter clock wise. Further, the absolute value “0.25” indicates its angle between the lines at open ratio is 1 and 0.25.

A line described by dotted line indicates the louver 211 rotates in counter clock wise by angle L2 where the angle L2 is greater than the angle L1. At this angle, it is defined that the open ratio is +0.1. In this case, the attached sign “+” is referred that the direction of its rotation is in counter clock wise. Further, the absolute value “0.1” indicates its angle between the lines at open ratio is 1 and 0.1.

Next, the relation between the open ratio and CR will be described by referring FIG. 7. FIG. 7 is a table illustrates a relation between an open ratio and CR. The open ratio information memorized in the memory 280 includes the contents illustrated in the table. As shown in FIG. 7, the open ratio for motors M1, M2 and M3 is determined by CR respectively. More specifically, when CR is less than 0.33, the open ratio of motor M1 is +0.25, the open ratio of motor M2 is +0.1 and the open ratio of motor M3 is +0.1. When CR is equal to or more than 0.33 and less than 0.66, the open ratio of motor M1 is +0.25, the open ratio of motor M2 is +0.25 and the open ratio of motor M3 is +0.1. When CR is equal to or more than 0.66, the open ratio of motor M1 is 1, the open ratio of motor M2 is 1 and the open ratio of motor M3 is −0.25.

The CR value varies depending upon the current cooling capacity. The current cooling capacity is determined depending upon the temperature where the temperature sensor 213 is attached. Thus, shown in the FIG. 4, when the temperature is relatively high, CR value becomes relatively high (i.e. CR>=0.66). Accordingly, the liquid level becomes relatively high. In such case, the table shown in FIG. 7 indicates that the motors M1, M2 and M3 controls the louvers 211 so that the airflow profile to the heat exchanger 110 is dispersed in relatively broader.

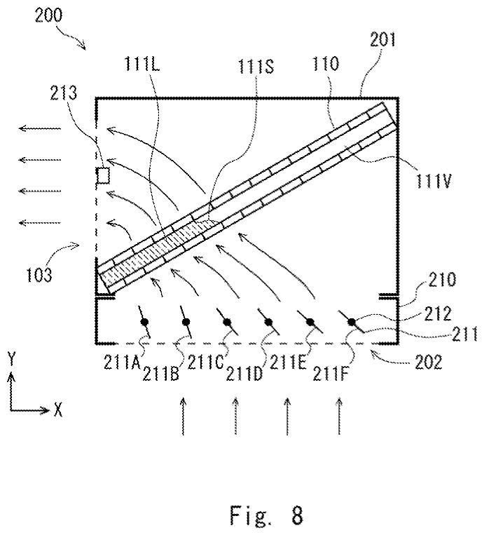

On contrast, when the temperature is relatively low, CR value becomes relatively low (i.e. CR<0.33). Accordingly, the liquid level becomes relatively low. FIG. 8 is a second schematic view of a cooling system according to a second example embodiment. The cooling system shown in FIG. 8 is described in response to the case that CR is less than 0.33 in FIG. 7. In such case, the table shown in FIG. 7 indicates that the motors M1, M2 and M3 controls the louvers 211 so that the airflow profile to the heat exchanger 110 is relatively concentrated in lower left area.

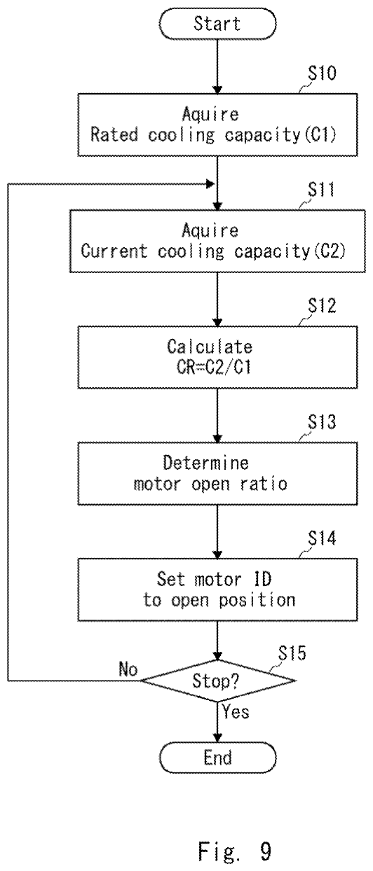

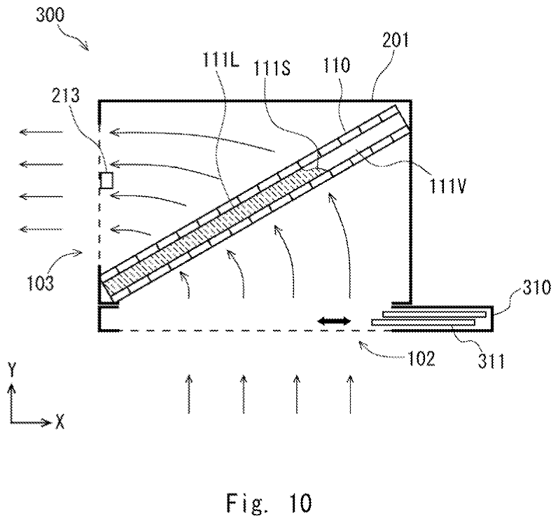

Next, process performed by the cooling system is described with reference to FIG. 9. FIG. 9 is a flowchart of the cooling system according to the second example embodiment. The flowchart shown in FIG. 9 is a series of a process which the controller 270 executes.

Firstly, the controller 270 acquires rated cooling capacity C1 (Step S10). The controller 270 may acquire the rated cooling capacity C1 from a user, or other system.

The controller 270 then acquires current cooling capacity C2 (Step S11). The controller may acquire the current cooling capacity by receiving the temperature data from temperature sensor 213 and calculating above mentioned equation (1) and (2).

Further, the controller 270 calculates CR (Step S12). CR is calculated by dividing C1 to C2.

Next, the controller 270 fetches the open ratio information from memory 280 and determines the open ratio of motors M1, M2 and M3 (Step S13) by referring the CR and the open ratio information.

The controller 270 then indicates the driver 290 to set the motors M1, M2 and M3 in a determined open ratio (Step S14).

Next, the controller 270 determines whether to stop the series of process (step S15). For example, when the controller 270 detects the system powered off, the controller 270 determines to stop the series of process (step S15: Yes) and terminates the process. Meanwhile, if the controller 270 has determined not to stop the series of process (step S15: No), the controller 270 returns to step S11 and continues with the process.

By performing the above described process, it is possible that the cooling system 200 set airflow profile corresponding to the calculated liquid level.

Although the second example embodiment has been described above, the configuration according to the second example embodiment is not limited to the above-described configuration. For example, the fan unit 220 may be attached to the outlet 103 instead of the inlet 102 to pump the air exhausted from the cooling system 200 to the server module 400. The fan unit 220 may be attached to both the inlet 102 and the outlet 103. Also, composing the fan unit 220 is not mandatory. The number of the louvers and motors is not limited to above example. The louver unit 210 may have at least one louver. At least one motor is composed for the cooling system 200. The motor may control one or more louvers to be rotated. The cooling system 200 may have a mechanism which allows one motor to rotate a plural of louvers in different rotate ratio. The temperature sensor 220 may be attached to another point where the cooling system can acquire the current cooling capacity to control the refrigerant liquid level. The cooling system may have a plurality of temperature sensors. The cooling system may have a temperature sensor which can detect a temperature of the heat exchanger. By detecting the temperature of the heat exchanger, the cooling system can estimate the refrigerant liquid level.

As described above, it is possible to provide a cooling system and the like which can implement heat transfer with high efficiency.

### Third Example Embodiment

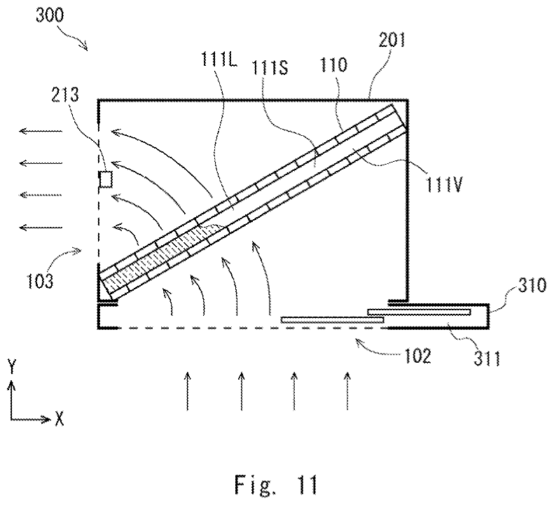

Third example embodiment will be described with referred to FIG. 10 and FIG. 11. FIG. 10 is a first schematic view of a cooling system according to the third example embodiment. The difference between the second example embodiment and the third example embodiment is structure of the air distribution controller. A cooling system 300 described in FIG. 10 has an air distribution controller 310 instead of the louver unit 210. The air distribution controller 310 has a plural of sliders 311. The sliders 311 are formed in a rectangular plate. The sliders 311 are mounted along the inlet 102 and can be slid in a direction in parallel to X-axis. The sliders 311 are controlled by a motor (not shown).

In the case shown in FIG. 10, the liquid level is relatively high. Therefore, it is desirable that the cooling system 300 distributes the air passage corresponding to the area. In an aspect of the cooling system 300 shown in FIG. 10, two sliders 311 are placed at a right side of the air distribution controller 310. Since the air distribution controller 310 has a space to house these sliders 311 at its right portion, the sliders 311 don't interrupt the airflow passing through the inlet 102. Accordingly, the air passes the area where the liquid refrigerant is contained.

FIG. 11 is a second schematic view of a cooling system according to the third example embodiment. In the case of FIG. 11, the liquid level is relatively low compared to the case of FIG. 10. In this case, the sliders 311 are placed from the right part to the center part of the inlet 102 so that the right air passage is blocked. Therefore, the air passes the area where the liquid refrigerant is contained.

In the case of this embodiment, the controller 270 can control the motor by referring the open ratio information similar to that in the case of the second example embodiment. Note that in this case, the open ratio may also be referred to aperture ratio, which refers to proportion of the opening of the inlet 102.

Note that the number of the sliders is not limited to the above configuration. The cooling system 300 may have at least one slider. The slider may have a telescopic motion mechanism. The slider may have characteristics such as flexibility or elasticity.

As described above, it is possible to provide a cooling system and the like which can implement heat transfer with high efficiency.

The program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (Read Only Memory), CD-R, CD-R/W, and semiconductor memories (such as mask ROM, PROM (Programmable ROM), EPROM (Erasable PROM), flash ROM, RAM (Random Access Memory), etc.).

The program may be provided to a computer using any type of transitory computer readable media. Examples of transitory computer readable media include electric signals, optical signals, and electromagnetic waves. Transitory computer readable media can provide the program to a computer via a wired communication line, such as electric wires and optical fibers, or a wireless communication line.

While the present invention has been described above with reference to exemplary embodiments, the present invention is not limited to the above exemplary embodiments. The configuration and details of the present invention can be modified in various ways which can be understood by those skilled in the art within the scope of the invention.

### INDUSTRIAL APPLICABILITY

The present invention is applicable to industries using data center including a server module, supercomputer, or mainframe computer system.

### REFERENCE SIGNS LIST

100, 200, 300 cooling system
101, 201 housing
102 inlet
103 outlet
110 heat exchanger
111 refrigerant
120, 310 air distribution controller
121, 212 axis
210 louver unit
211 louver
213 temperature sensor
220 fan unit
230 compressor
241 first pipe
242 second pipe
250 outdoor unit
260 valve unit

What is claimed is:

1. A cooling system for cooling a server module, the system comprising:
a housing including an inlet configured to receive air exhausted from the server module and an outlet configured to provide air to the server module;
a heat exchanger in which contains a refrigerant, being mounted between the inlet and the outlet, configured so that the refrigerant exchanges heat with air passing through the heat exchanger, wherein the heat exchanger accepts variation of the refrigerant liquid level; and
an air distribution controller, mounted in an inlet side of the heat exchanger, having at least one movable plate which allows an airflow profile from the inlet to the heat exchanger to be redirected;
wherein the air distribution controller controls the airflow profile depending upon the liquid level.

2. The cooling system according to claim 1 wherein
the air distribution controller has at least one plate, the plate rotating along an axis set in a direction orthogonal to the airflow direction.

3. The cooling system according to claim 1 wherein
the air distribution controller has a plurality of plates, each plate rotating respectively to redirect the airflow in a predetermined direction.

4. The cooling system according to claim 1 wherein
the angle of each of the plates is adjusted based upon the liquid level.

5. The cooling system according to claim 1 wherein
the air distribution controller has at least one plate, the plate sliding so as to change an area of an opening of the inlet for restricting the airflow.

6. The cooling system according to claim 1 wherein
the air distribution controller is configured to redirect the airflow profile in a manner that the airflow, when the liquid level is at a first position, is redirected toward a first area of the heat exchanger, and the airflow, when the liquid level is a second position, is redirected toward a second area of the heat exchanger, the first level being lower than the second level and the first area being smaller than the second area.

7. The cooling system according to claim 1 further comprising:
a driver configured to drive the air distribution controller; and
a controller configured to acquire a cooling capacity of the heat exchanger and to transmit an instruction signal to the driver.

8. The cooling system according to claim 7, further comprising
a temperature sensor configured to measure the temperature at a point between the heat exchanger and the outlet, wherein
the controller is configured to acquire the cooling capacity based upon the temperature.

9. A cooling method for a cooling system, the cooling system includes a heat exchanger containing a refrigerant and an air distribution controller, comprising:
an acquiring a cooling capacity step in which the cooling capacity of the heat exchanger is calculated based on a temperature at predetermined point of the cooling system;
an liquid level estimation step which the liquid level of the heat exchanger is estimated based upon the cooling capacity; and
an air distribution control step which the air distribution controller redirects the airflow profile depending upon the liquid level.

10. A non-transitory computer readable medium storing a program for causing a computer to execute a cooling method for a cooling system, comprising:
an acquiring a cooling capacity step which the cooling capacity of the heat exchanger is calculated based on a temperature at predetermined point of the cooling system;
an liquid level estimation step which the liquid level of the heat exchanger is estimated based upon the cooling capacity; and
an air distribution control step in which the air distribution controller redirects the airflow profile depending upon the liquid level.
